(19) United States
(12) Patent Application Publication
(10) Pub. No.: US 2007/0296428 A1
(43) Pub. Date: Dec. 27, 2007

(54) SEMICONDUCTOR DEVICE HAVING SUPPLY VOLTAGE MONITORING FUNCTION

(75) Inventors: Yuji KOBAYASHI, Kanagawa (JP); Kazunori OZAWA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/760,854

(22) Filed: Jun. 11, 2007

(30) Foreign Application Priority Data
Jun. 13, 2006 (JP) 2006-163288

(51) Int. Cl. G01R 31/02

(52) U.S. Cl. 324/754

(57) ABSTRACT

A semiconductor device with the function of monitoring the rise time of the supply voltage at power on is provided. The semiconductor device includes an electrode pad, an internal circuit and a monitoring unit. An input power source supplies the internal supply voltage to the internal circuit via the electrode pad. The internal circuit normally operates when the internal supply voltage is within an operating voltage range. The monitoring unit monitors the interval between the time when the internal supply voltage is a set voltage and the time when the internal supply voltage is changed to the operating voltage range as the rise time.

### BACKGROUND OF THE INVENTION

1. Field of the Invention

The present invention relates to a semiconductor device having supply voltage monitoring function.

2. Description of the Related Art

On a semiconductor wafer, semiconductor devices (semiconductor chips) are formed in an arrangement of matrix. In each of the semiconductor devices, an internal circuit for executing an objected function and electrode pads connected to the internal circuit are formed. After the semiconductor devices are formed, electric characteristic verification tests are performed.

One of the electric characteristic verification tests is a probe test. The probe test is performed by using measuring devices such as tester or storage oscilloscope with a probe provided at external terminals connected to the electrode pad of the semiconductor device. In a probe test, a supply voltage is monitored. As the monitoring technology of supply voltage, (A) simply monitoring a supply voltage; and (B) monitoring the rise time of a supply voltage upon power-on are exemplified.

Here, some examples of the arts relating to the technology (A) will be introduced below.

Japanese Utility Model Application (Laid-Open) No. JP-A-Heisei 03-68078 U discloses a voltage monitor. The voltage monitor detects irregularity of the voltage of monitoring target. This voltage monitor is characterized by: being provided with an analog-digital converter which converts the target voltage into digital data, a memory which stores predetermined voltage data, and means adapted to compare the digital data and the voltage data with each other; and detecting based on a result of this comparison, irregularity of the voltage described above.

Japanese Utility Model Application (Laid-Open) No. JP-A-Heisei 03-113936 U discloses a monitoring controller. The monitoring controller converts an analog amount, which has been detected from a monitoring target and inputted via signal input means, into a digital amount by analog-digital conversion means, and then monitors the monitoring target based on the digital amount. The monitoring controller is provided with a power source device serving as a power source of each means. The secondary side output of the power source device is connected to the input side of the signal input means. The monitoring controller is further provided with: alarm means adapted to give an alarm; reference value supply means adapted to supply a reference value indicating a permitted range of a secondary side voltage of the power source device; judgment means adapted to judge whether or not a digital value of the secondary side voltage of the power source device obtained from the analog-digital conversion means is within a range of reference values obtained from the reference value supply means; and control means adapted to activate the alarm means when the judgment means judges that the digital value of the secondary side voltage of the power source device is out of the range of reference values.

Next, the technology (B) described above will be described below.

A supply voltage is supplied by an input power source to the electrode pad of the semiconductor device. The supply voltage is supplied to the internal circuit of the semiconductor device as an internal supply voltage. The internal circuit operates when the internal supply voltage is a working voltage. To monitor the rise time of the supply voltage upon power-on through a probe test, as a position corresponding to the electrode pad described above, a probe is provided on a signal line connecting the input power source and the electrode pad together. The measuring device measures by probes the supply voltage applied by the input power source to the signal line. The technology (B) described above enables the judgment of a failure occurring in the semiconductor device by monitoring the rise time of the supply voltage upon power-on.

### SUMMARY

With the aforementioned technology (B), the rise time of the supply voltage at power-on is monitored by the probe test, as described above. However, the supply voltage measured through the probe test is not an internal supply voltage supplied to the internal circuit of the semiconductor device but an external terminal voltage as a supply voltage applied to the signal line. Due to the influences of voltage drop, wiring, or the like inside the semiconductor device, the internal supply voltage is not necessarily identical to the external terminal voltage. Thus, measuring the external terminal voltage through the probe test in order to monitor the rise time of the supply voltage upon power-on does not result in measuring the internal supply voltage.

Further, the technology (B) described above, in order to conduct the probe test, the probe and the measuring device in addition to the power source are required.

Moreover, with the aforementioned technology (B), the probe test can be conducted after production of the semiconductor device, but is difficult to conduct after shipment of the semiconductor device. For example, by performing the probe test after the production of the semiconductor device, a failure occurring in the semiconductor device can be judged. However, when a failure occurs after the shipment of the semiconductor device, it is difficult to investigate the cause of the failure before the probe test is conducted. Thus, the cause of the problem cannot be investigated in real-time.

According to an aspect of the present invention, a semiconductor device includes: an electrode pad to which a supply voltage is supplied from an input power source; an internal circuit to which the supply voltage is supplied as an internal supply voltage and configured to operate when the internal supply voltage is within a range of an operating voltage; and a monitoring unit configured to monitor a rise time of the internal supply voltage changing from a set voltage set to be lower than the operating voltage to the operating voltage.

With the configuration described above, the semiconductor device according to the present invention can provide the function of measuring the rise time of an internal supply voltage upon power-on. Consequently, a probe and a measuring device are not necessarily required according. Thus, according to the present invention, even after production of the semiconductor device and even after shipment of the semiconductor device, the rise time of the internal supply voltage upon power-on can be measured. Thus, in the event of failure occurring in the semiconductor device, the cause of the failure can be investigated in real-time.

### BRIEF DESCRIPTION OF THE DRAWINGS

FIG. 1 shows the configuration of a semiconductor system applied to a semiconductor device according to the first embodiment of the present invention;

FIG. 2 shows the configuration of the voltage comparison section of a monitoring unit of the semiconductor device 1 according to the first embodiment of the present invention;

FIG. 3 shows the configuration of the monitoring controller of the monitoring unit of a semiconductor device according to the first embodiment of the present invention;

FIG. 4 is a timing chart showing an operation in the test mode as the operation of the semiconductor system applied to the semiconductor device according to the first embodiment of the present invention;

FIG. 5 is a diagram for explaining a semiconductor device according to the second embodiment of the present invention;

FIG. 6 shows the configuration of a semiconductor system applied to the semiconductor device according to the second embodiment of the present invention;

FIG. 7 shows the configuration of the monitoring controller of the monitoring unit of the semiconductor device according to the second embodiment of the present invention; and

FIG. 8 is a timing chart showing an operation in a test mode as the operation of the semiconductor system applied to the semiconductor device according to the second embodiment of the present invention.

### DETAILED DESCRIPTION OF PREFERRED EMBODIMENTS

Hereinafter, embodiments of the semiconductor device according to the present invention will be described in detail referring to the accompanying drawings.

### First Embodiment

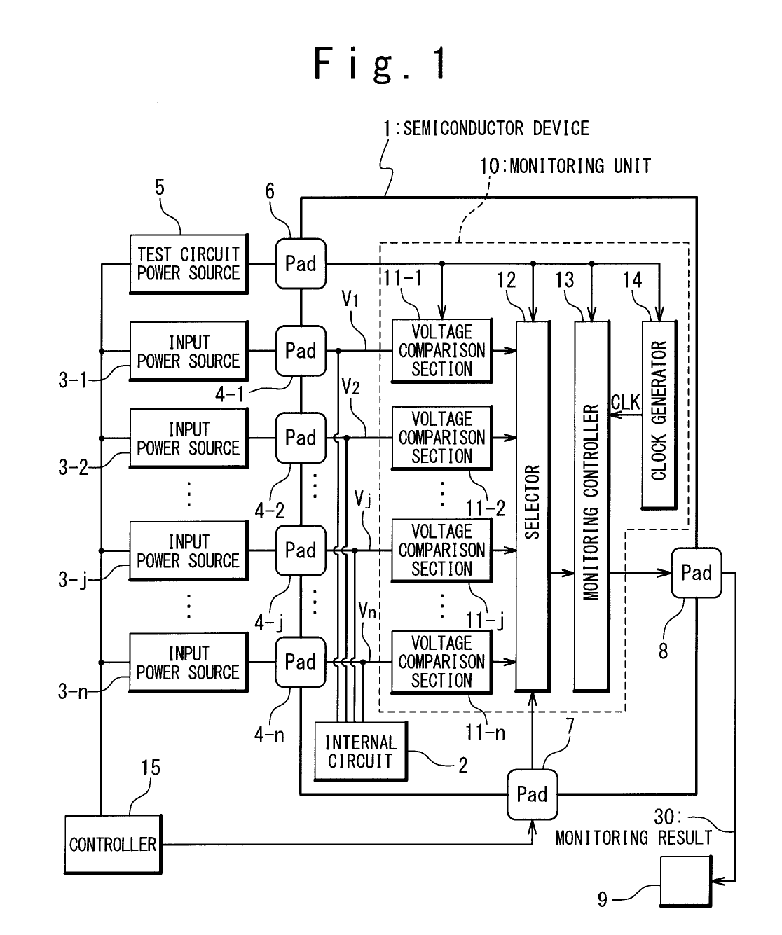

FIG. 1 shows the configuration of a semiconductor system applied to the semiconductor device according to a first embodiment of the present invention. The semiconductor system is a computer, and includes a semiconductor device 1; n-number of input power sources 3-1 to 3-n (where n is an integer number of 1 or larger); a test circuit power source 5; an output device 9; and a controller 15. The output device 9 is an alarm device emitting a sound or a display device.

The semiconductor device 1 includes an internal circuit 2, n-number of electrode pads 4-1 to 4-n, a test execution electrode pad 6, a selection electrode pad 7, a result output electrode pad 8, and a monitoring unit 10.

The controller 15 is connected to the n-number of input power sources 3-1 to 3-n via n-number of signal lines, connected to the test circuit power source 5 via a signal line, and connected to the selection electrode pad 7 via a signal line.

The n-number of electrode pads 4-1 to 4-n are respectively connected to the n-number of input sources 3-1 to 3-n via n-number of signal lines, and connected to the internal circuit 2 and the monitoring unit 10 inside the semiconductor device 1.

Test execution electrode pad 6 is connected to the test circuit power source 5 via a signal line, and connected to the monitoring unit 10 inside the semiconductor device 1.

The selection electrode pad 7 is connected to the monitoring unit 10 inside the semiconductor device 1.

The result output electrode pad 8 is connected to the output device 9 via a signal line, and connected to the monitoring unit 10 inside the semiconductor device 1.

The controller 15 is operated by, for example, a computer program, and executes the operations of a normal operation mode or a test mode.

In the normal operation mode, the internal circuit 2 is operated. The normal operation mode is executed by, for example, the controller 15 after a shipment of the semiconductor system. The controller 15 executes the normal operation mode in response to a user's power-on instruction, and ends the execution of the normal operation mode in response to a user's power-on ending instruction.

In the test mode, the rise time of a supply voltage upon power-on is monitored. The test mode is executed by, for example, the controller 15 after the production of the semiconductor device 1. In this case, the controller 15 executes the test mode in response to an operator's operation. For example, the test mode is executed by the controller 15 when the normal operation mode is not executed after the shipment of the semiconductor system. In this case, the controller 15 executes the test mode at a set time.

In the normal operation mode, the controller 15 controls the n-number of input power sources 3-1 to 3-n by respective digital signals so as to supply n-number of supply voltages.

In this case, the n-number of input power sources 3-1 to 3-n supply the n-number of supply voltages to the n-number of electrode pads 4-1 to 4-n of the semiconductor device 1. At this time, to the internal circuit 2 of the semiconductor device 1, the n-number of supply voltages are supplied as internal supply voltages V₁ to Vₙ. The internal circuit 2 operates when the internal supply voltages V₁ to Vₙ are operating voltages V_{1typ} to V_{ntyp}, respectively.

In the test mode, the controller 15 controls the test circuit power source 5 so that a test supply voltage is supplied as a test mode signal. The controller 15 also controls the input power source 3-j of the n-number of input power sources 3-1 to 3-n so that the j-th supply voltage (where j is an integer satisfying 1≦j≦n) of the n-number of supply voltages described above is supplied. Simultaneously therewith, the controller 15 outputs a j-th selected signal to the monitoring unit 10 of the semiconductor device 1 via the selection electrode pad 7.

In this case, the test supply voltage is supplied by the test circuit power source 5 to the monitoring unit 10 via the test execution electrode pad 6 of the semiconductor device 1. The j-th supply voltage is supplied by the input power source 3-j to the electrode pad 4-j of the semiconductor device 1. At this point of time, to the internal circuit 2 of the semiconductor device 1, the j-th supply voltage is supplied as the internal supply voltage Vⱼ. The monitoring unit 10, in response to the test supply voltage, the internal supply voltage Vⱼ, and the j-th selected signal, monitors a rise time tⱼ when the internal supply voltage Vⱼ changes from a set voltage Vⱼₛₜ to the operating voltage V_{jtyp} which is higher than the set voltage Vⱼₛₜ. The monitoring unit 10 outputs a result of the rise time of the internal supply voltage Vⱼ monitored at power-on as a monitoring result 30 to the output device 9 via the result output electrode pad 8. In a case where the output device 9 is an alarm device, the monitoring result 30 is outputted by sound. In a case where the output device 9 is a display device, the monitoring result 30 is displayed on the display device.

The monitoring unit 10 includes n-number of voltage comparison sections 11-1 to 11-n, a selector 12, a monitoring controller 13, and a clock generator 14. The voltage comparison sections 11-1 to 11-n, the selector 12, the monitoring controller 13, and the clock generator 14 operate in response to the test supply voltage. The clock generator 14, when the test supply voltage is being inputted, generates a cyclic clock signal CLK and outputs it to the monitoring controller 13.

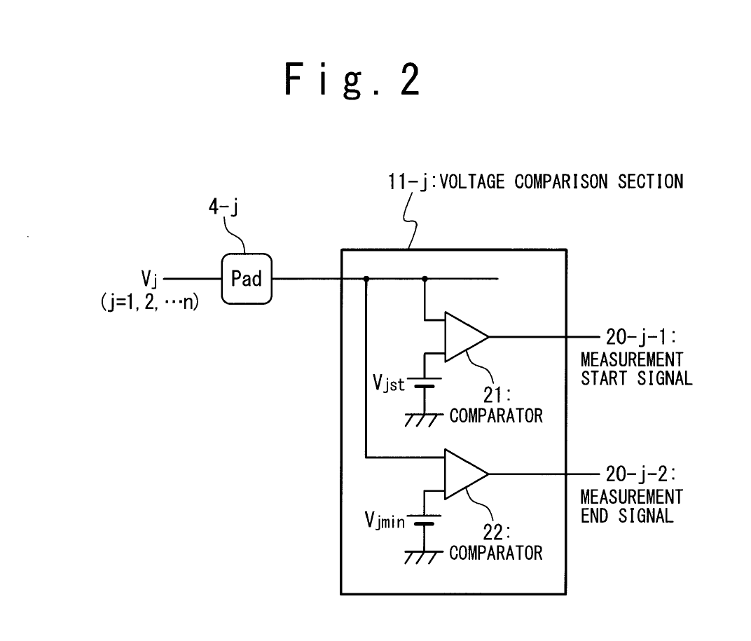

FIG. 2 shows the configuration of the voltage comparison section 11-j (where j is equal to 1, 2, . . . , or n). The voltage comparison section 11-j includes a measurement start comparator 21 and a measurement end comparator 22.

The measurement start comparator 21 has two input terminals and an output terminal. The internal supply voltage Vⱼ is supplied to one of the two inputs, and the set voltage Vⱼₛₜ is supplied to the other input. The output is connected to the selector 12. The set voltage Vⱼₛₜ is expressed by, for example, 0.1 V_{jtyp} which corresponds to a voltage of 10% of the operating voltage V_{jtyp}.

When the internal supply voltage Vⱼ is equal to or larger than the set voltage Vⱼₛₜ, the measurement start comparator 21 sets the signal level of a measurement start signal 20-j-1 high and then outputs this measurement start signal 20-j-1.

The measurement end comparator 22 has two input terminals and an output terminal. The internal supply voltage Vⱼ is supplied to one of the two inputs, and a minimum operating voltage Vⱼₘᵢₙ is supplied as the operating voltage V_{jtyp} to the other input. The output is connected to the selector 12. The minimum operating voltage Vⱼₘᵢₙ is a minimum voltage required for operating the internal circuit 2, and is expressed by, for example, 0.9 V_{jtyp} which corresponds to a voltage of 90% of the operating voltage V_{jtyp}.

When the internal supply voltage Vⱼ is being equal to or larger than the minimum operating voltage Vⱼₘᵢₙ, the measurement end comparator 22 sets the signal level of a measurement end signal 20-j-2 high and then outputs this measurement end signal 20-j-2.

The selector 12, in response to the j-th selected signal, selects the output of the voltage comparison section 11-j of the n-number from the voltage comparison sections 11-1 to 11-n and outputs the selected one to the monitoring controller 13. The monitoring controller 13 monitors a rise time tⱼ from when the measurement start signal 20-j-1 from the voltage comparison section 11-j is inputted to when the measurement end signal 20-j-2 from the voltage comparison section 11-j is inputted.

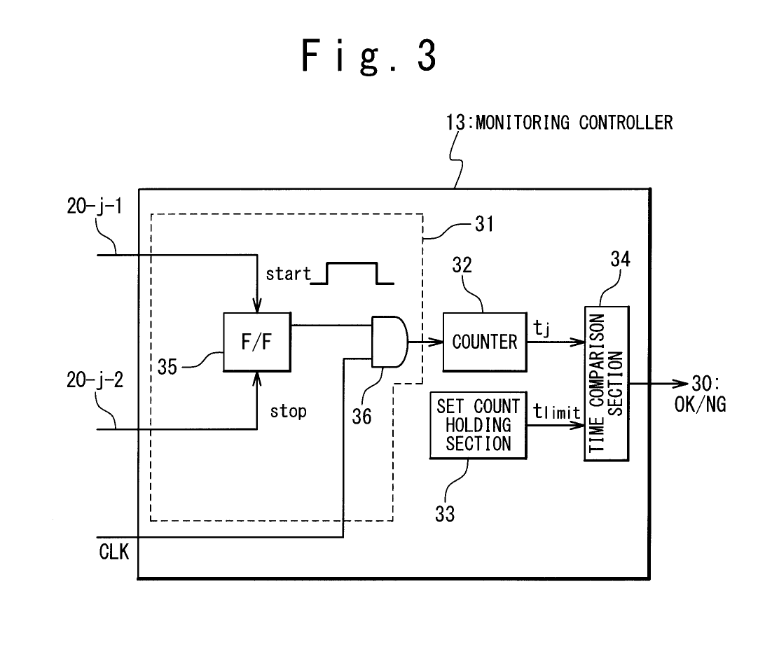

FIG. 3 shows a configuration of the monitoring controller 13. The monitoring controller 13 includes a counter controller 31, a counter 32, a set count holding section 33, and a time comparison section 34.

The counter controller 31, in response to a transition of the measurement start signal 20-j-1 from the low level to the high level, controls the counter 32 so as to start the counting of the clock signal CLK. That is, the counter 32 starts counting of the rise time tⱼ described above. The counter controller 31, in response to a transition edge of the measurement end signal 20-j-2 from the low level to the high level, controls the counter 32 so as to end the counting of the clock signal CLK. That is, the counter 32 ends the counting of the rise time tⱼ described above.

The counter controller 31 can be realized by using, for example, an RS flip-flop 35 and an AND circuit 36.

The RS flip-flop35 has an input terminal R, an input terminal S, and an output terminal Q. The internal circuit measurement start signal 20-j-1 is inputted to the input S described above. The measurement end signal 20-j-2 is inputted to the input R described above.

The AND circuit 36 has two input terminals and an output terminal. To one of the two inputs, the output Q of the RS flip-flop35 is connected. To the other one of the two inputs of the AND circuit 36, the clock signal CLK is supplied. The output of the AND circuit 36 is connected to the counter 32.

In response to the transition edge of the measurement start signal 20-j-1 to a high level, the RS flip-flop 35 sets the output signal level high, and outputs this high level output signal to the AND circuit 36. While the output of the RS flip-flop35 is at the high level, the AND circuit 36 outputs the clock signal CLK to the counter 32, and then the counter 32 counts the clock signal.

In response to the transition edge of the measurement end signal 20-j-2 to a high level, the RS flip-flop35 sets the output signal level low, and outputs this low level output signal to the AND circuit 36. When the output of the RS flip-flop35 turns to the low level, the AND circuit 36 stops the outputting of the clock signal CLK to the counter 32, and then the counter 32 ends the counting of the clock signal CLK.

The set count holding section 33 holds a set count value tₗᵢₘᵢₜ. The time comparison section 34 compares a count value tⱼ counted by the counter 32 and the set count value tₗᵢₘᵢₜ and then outputs a result of this comparison as a monitoring result 30.

For example, assume that the set count value tₗᵢₘᵢₜ is 100 [ms]. Assume also that the clock generator 14 outputs the clock signals CLK at intervals of 1 [ms] and that the counter 32 counts one for each [ms].

Thus, the time comparison section 34, when the count value tⱼ is within 100 [ms], outputs the normal information OK as the monitoring result 30 to the output device 9 via the result output electrode pad 8. The normal information OK indicates that the rise time of the internal supply voltage Vⱼ is equal to or smaller than the desired value tₗᵢₘᵢₜ.

On the other hand, the time comparison section 34, when the count value tⱼ exceeds 100 [ms], outputs the irregular information NG as the monitoring result 30 to the output device 9 via the result output electrode pad 8. The irregular information NG indicates that the rise time of the internal supply voltage Vⱼ is neither equal to nor smaller than the desired value tₗᵢₘᵢₜ.

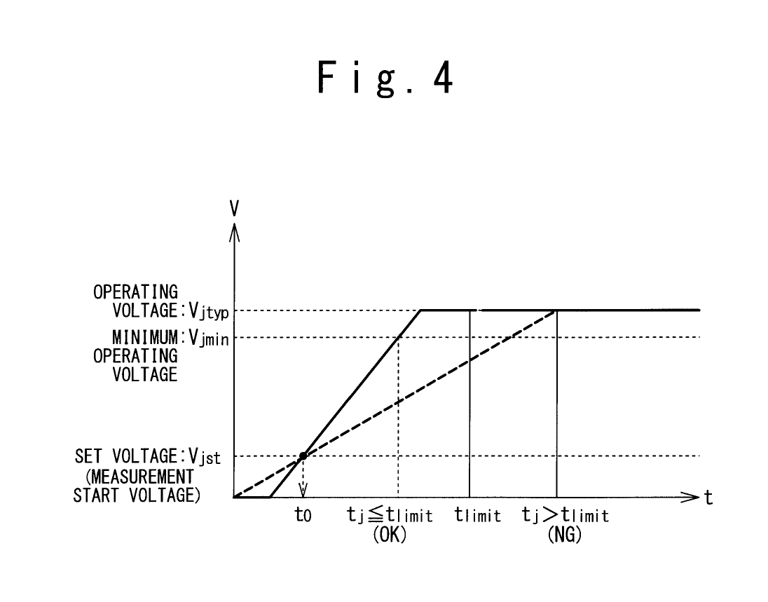

FIG. 4 is a timing chart showing the operation in the test mode as operation of the semiconductor system applied to an embodiment of the semiconductor device 1 of the present invention.

First, the controller 15 controls the test circuit power source 5 so as to execute the test mode. In this case, the test circuit power source 5 supplies a test supply voltage (test mode signal) to the monitoring unit 10 via the test execution electrode pad 6. The monitoring unit 10, in response to the test mode signal, executes the test mode. At this point of time, the clock generator 14 of the monitoring unit 10, in response to the test mode signal, generates the clock signal CLK and outputs it to the monitoring controller 13.

Next, the controller 15 controls the input power source 3-j so as to monitor the rise time of the internal supply voltage Vⱼ when the input power source 3-j supplies the j-th supply voltage to the semiconductor device 1. In this case, the input power source 3-j supplies the j-th supply voltage to the electrode pad 4-j. At this point of time, the j-th supply voltage is supplied as the internal supply voltage Vⱼ to the internal circuit 2. Moreover, the internal supply voltage Vⱼ is supplied to the voltage comparison section 11-j of the monitoring unit 10.

The controller 15 controls the input power source 3-j and also, at the same time, outputs the j-th selected signal to the monitoring unit 10 of the semiconductor device 1 via the selection electrode pad 7. In this case, the selector 12 of the monitoring unit 10, in response to the j-th selected signal, outputs output of the voltage comparison section 11-j to the monitoring controller 13.

The internal supply voltage Vⱼ is smaller than the set voltage Vⱼₛₜ (t<t0). In this case, the measurement start comparator 21 and the measurement end comparator 22 of the voltage comparison section 11-j respectively set the signal levels of the measurement start signal 20-j-1 and the measurement end signal 20-j-2 low.

The internal supply voltage Vⱼ is equal to or larger than the set voltage Vⱼₛₜ and also smaller than the minimum operating voltage Vⱼₘᵢₙ. (t₀≦t) In this case, the measurement start comparator 21 sets the signal level of the measurement start signal 20-j-1 high.

In response to the transition edge of the measurement start signal 20-j-1 to the high level, the RS flip-flop35 of the monitoring controller 13 sets the output signal level high. The AND circuit 36, when the signal level of the output signal from the RS flip-flop35 is high, outputs the clock signal CLK. The counter 32 adds 1 when the signal level of the output signal form the AND circuit 36 changes from low to high.

When the internal supply voltage Vⱼ becomes equal to or larger than the minimum operating voltage Vⱼₘᵢₙ (tⱼ=t−t₀), the measurement end comparator 22 sets the signal level of the measurement end signal 20-j-2 high.

In response to the transition edge of the measurement end signal 20-j-2 to the high level, the RS flip-flop35 sets the output signal level low. Since the signal level of the output signal from the RS flip-flop35 is low, the AND circuit 36 stops the outputting of the clock signal CLK, and the counter 32 ends the counting.

The time comparison section 34 compares the count value tⱼ counted by the counter 32 and the set count value tₗᵢₘᵢₜ.

The count value tⱼ is within the set count value tₗᵢₘᵢₜ (tⱼ≦tₗᵢₘᵢₜ). In this case, the time comparison section time 34 outputs the normal information OK as the monitoring result to the output device 9 via the result output electrode pad 8. The normal information OK indicates that the rise time of the internal supply voltage Vⱼ is equal to or smaller than the desired value tₗᵢₘᵢₜ.

The count value tⱼ exceeds the set count value tₗᵢₘᵢₜ (tⱼ>tₗᵢₘᵢₜ). In this case, the time comparison section time 34 outputs the irregular information NG as the monitoring result 30 to the output device 9 via the result output electrode pad 8. The irregular information NG indicates that the rise time of the internal supply voltage Vⱼ is neither equal to nor smaller than the desired value tₗᵢₘᵢₜ.

In the test mode, the operation for j described above is performed from 1 to n.

Based on the description given above, the semiconductor device 1 according to the first embodiment of the present invention measures the rise time of the internal supply voltage Vⱼ upon power-on. Consequently, the preparation of a probe and a measuring instrument is not required. Thus, the rise time of the internal supply voltage Vⱼ upon power-on can be measured even after the semiconductor device 1 is produced and also even in a case where the semiconductor device 1 is shipped. Thus, in the event of failure occurring in the semiconductor device 1, the cause of this failure can be investigated in real-time.

### Second Embodiment

For a semiconductor device 1 according to a second embodiment of the present invention, only points different from the semiconductor device 1 according to the first embodiment will be described below.

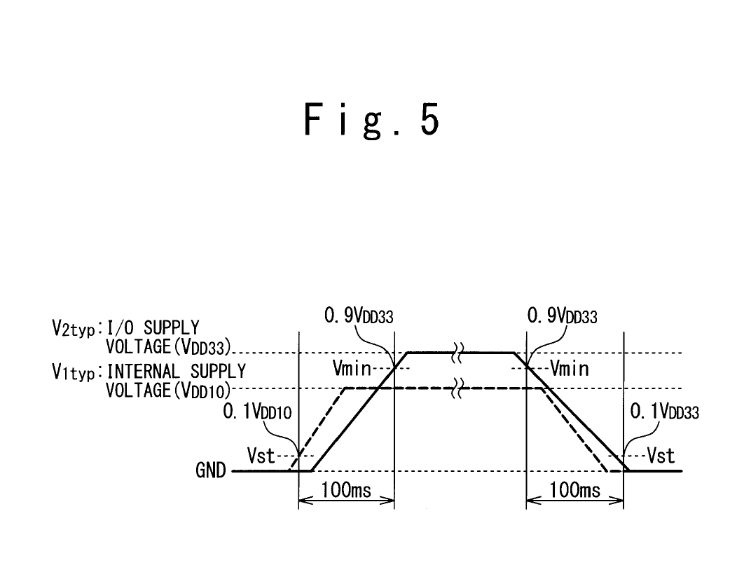

As shown in FIG. 5, internal supply voltages supplied to an internal circuit 2 of the semiconductor device 1 include an internal supply voltage V_{DD10} for operating the internal circuit 2, and an I/O supply voltage V_{DD33} supplied to operate at least one input-output circuit (which is also called as an interface block) for inputting and outputting a signal to and from the internal circuit 2. In this case, assume that n described above (in the first embodiment) is 2, that an operating voltage V_{1typ} for the internal supply voltage V₁ described above is the internal supply voltage V_{DD10} and that an operating voltage V_{2typ} for the internal supply voltage V₂ described above is the I/O supply voltage V_{DD33}. Then, assume that the internal supply voltage V_{DD10} is 1.0 [V], and that the I/O supply voltage V_{DD33} is 3.3 [V]. The set voltages V₁ₛₜ and V_{2nd} described above are expressed by 0.1V_{DD10} and 0.1V_{DD33}, respectively, which correspond to voltages of 10% of the internal supply voltage V_{DD10} and the input-output supply voltage V_{DD33}, respectively. The minimum operating voltages V₁ₘᵢₙ and V₂ₘᵢₙ are expressed by 0.9V_{DD10} and 0.9V_{DD33}, respectively, which correspond to voltages of 90% of the internal supply voltage V_{DD10} and the input-output supply voltage V_{DD33}, respectively.

For the semiconductor device 1, the order in which the internal supply voltage V_{DD10} and the input-output supply voltage V_{DD33} are supplied to the internal circuit 2 (power-on order) may not be particularly specified. However, there is a case that the time difference between the supply of the internal supply voltage V_{DD10} and the supply of the I/O supply voltage V_{DD33} to the internal circuit 2 (power-on time difference) is prescribed. About the prescription of the power-on time difference, it is recommended that the time from when either of the internal supply voltage V₁ and the internal supply voltage V₂ reaches the set voltage (0.1V_{DD10} or 0.1V_{DD33}) to when both the internal supply voltage V₁ and the internal supply voltage V₂ reach the minimum operating voltages 0.9V_{DD10} and 0.9V_{DD33}, respectively is within 100 [ms].

The semiconductor device 1 according to the second embodiment of the present invention executes the test mode for the specification of the power-on time difference described above.

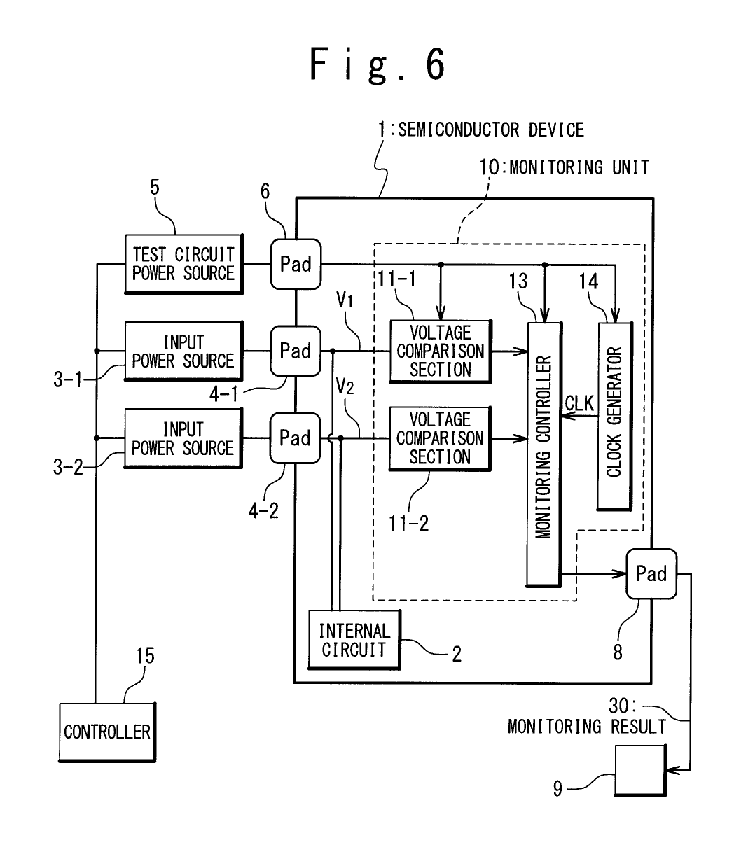

FIG. 6 shows the configuration of the semiconductor system applied to the semiconductor device 1 according to the second embodiment of the present invention. The semiconductor system includes, instead of the n-number of input power sources 3-1 to 3-n in the first embodiment, two input power sources 3-1 and 3-2 (n=2).

The semiconductor device 1 includes, instead of the n-number of electrode pads 4-1 to 4-n and the selection electrode pad 7, two electrode pads 4-1 and 4-2 (n=2).

A monitoring unit 10 of the semiconductor device 1 includes, instead of the n-number of voltage comparison sections 11-1 to 11-n and the selector 12, two voltage comparison sections 11-1 and 11-2 (n=2).

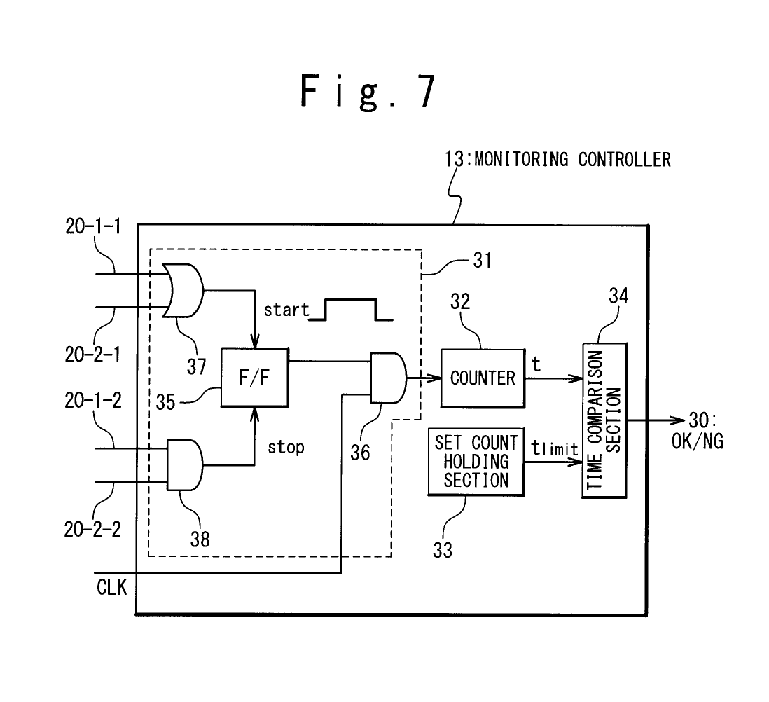

FIG. 7 shows the configuration of the monitoring controller 13 of the monitoring unit 10. A counter controller 31 of the monitoring controller 13 achieves its function by the configuration including, for example, in addition to an RS flip-flop35 and an AND circuit 36, an OR circuit 37 and an AND circuit 38.

The OR circuit 37 has two input terminals and an output terminal. A measurement start signal 20-1-1 is inputted to one of the two inputs and a measurement start signal 20-2-1 is inputted to the other one of the two inputs. The output terminal is connected to an input S of the RS flip-flop35.

The AND circuit 38 has two input terminals and an output terminal. A measurement end signal 20-1-2 is inputted to one of the two inputs and a measurement end signal 20-2-2 is inputted to the other one of the two inputs. The output terminal is connected to an input R of the RS flip-flop35.

When the signal level of either of the measurement start signals 20-1-1 or the 20-2-1 transits to the high level, the OR circuit 37 sets the output signal level high, and outputs the high output signal to the RS flip-flop35. The RS flip-flop35 sets the output signal level high, and outputs the high output signal to the AND circuit 36. While the output of the RS flip-flop35 is high, the AND circuit 36 outputs the clock signal CLK to the counter 32, and then the counter 32 counts the clock signal.

When the signal levels of both the measurement end signals 20-1-2 and 20-2-2 become high, the RS flip-flop35 sets the output signal level low, and outputs the low output signal to the AND circuit 36. When the output of the RS flip-flop35 becomes low, the AND circuit 36 stops the outputting of the clock signal CLK to the counter 32 and then the counter 32 ends the counting of the clock signal.

The set count holding section 33 holds a set count value tₗᵢₘᵢₜ. For example, assume that, as prescription of the power-on time difference, the set count value tₗᵢₘᵢₜ is 100 [ms]. Also assume that a clock generator 14 outputs the clock signal CLK at intervals of 1 [ms], and that the counter 32 counts one by one for each 1 [ms]. The time comparison section 34 compares a count value t₁₂ counted by the counter 32 and the set count value tₗᵢₘᵢₜ, and outputs a result of this comparison as a monitoring result 30.

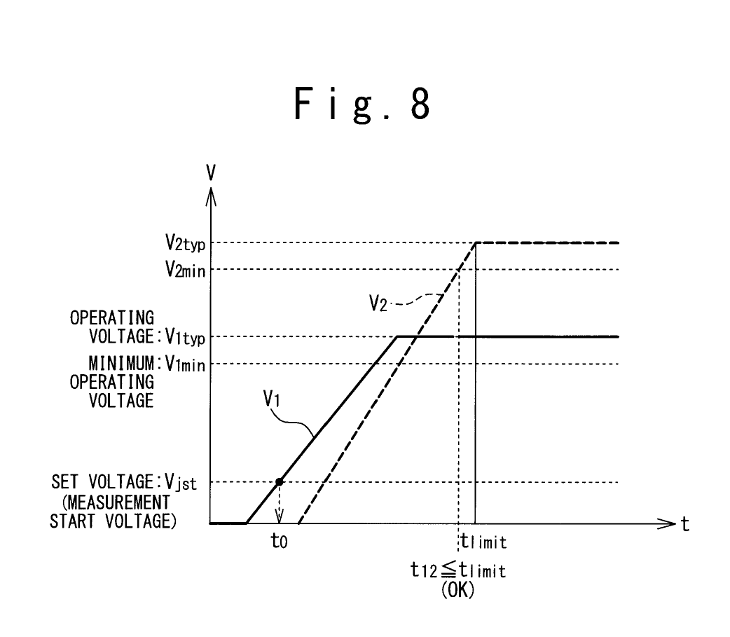

FIG. 8 is a timing chart showing the operation in the test mode as operation of the semiconductor system applied to the semiconductor device 1 of this embodiment of the present invention.

First, the controller 15 controls the test circuit power source 5 so as to execute the test mode. In this case, the test circuit power source 5 supplies a test supply voltage (test mode signal) to the monitoring unit 10 via a test execution electrode pad 6. The monitoring unit 10 executes the test mode in response to the test mode signal. At this time, the clock generator 14 of the monitoring unit 10, in response to the test mode signal, generates the clock signal CLK and outputs it to the monitoring controller 13.

Next, the controller 15 controls the input power sources 3-1 and 3-2 so as to monitor a difference in the rise time between the internal supply voltages V₁ and V₂ when the input power sources 3-1 and 3-2 respectively supply the first and second supply voltages to the semiconductor device 1. In this case, the input power sources 3-1 and 3-2 respectively supply the first and second supply voltages to the electrode pads 4-1 and 4-2. At this time, the first and second supply voltages are supplied as the internal supply voltages V₁ and V₂ to the internal circuit 2. Moreover, the internal supply voltages V₁ and V₂ are respectively supplied to the voltage comparison sections 11-1 and 11-2 of the monitoring unit 10.

The internal supply voltages V₁ and V₂ are smaller than the set voltages V₁ₛₜ and V_{2nd}, respectively (t<t0). In this case, a measurement start comparator 21 and a measurement end comparator 22 of the voltage comparison sections 11-1 and 11-2 respectively set the signal levels of the measurement start signals 20-1-1 and 20-2-1 and the measurement end signals 20-1-2 and 20-2-2 low.

For example, the internal supply voltage V₁ becomes equal to or larger than the set voltage V₁ₛₜ and smaller than the minimum operating voltage V₁ₘᵢₙ (t₀≦t). In this case, the measurement start comparator 22 of the voltage comparison section 11-1 sets the signal level of the measurement start signal 20-1-1 high.

In response to the transition edge of the measurement start signal 20-1-1 to the high level, the OR circuit 37 of the monitoring controller 13 sets the output signal level high. The RS flip-flop35, in response to the transition edge of the output level of the OR circuit 37 to the high level, sets the output signal level high. The AND circuit 36, when the signal level of the output signal from the RS flip-flop35 is high, outputs the clock signal CLK. The counter 32 adds 1 when the signal level of the output signal from the AND circuit 36 changes from low to high.

Next, the internal supply voltage V₂ is equal to or larger than the set voltage V_{2nd} and also smaller than the minimum operating voltage V₂ₘᵢₙ (t₀≦t). In this case, the measurement start comparator 21 of the voltage comparison section 11-2 sets the signal level of the measurement start signal 20-2-1 high.

At this point of time, the OR circuit 37 and the RS flip-flop35 of the monitoring controller 13 holds the output signal level, and the AND circuit 36 outputs the clock signal CLK. The counter 32 adds 1 when the output signal level signal from the AND circuit 36 changes from low to high.

For example, when the internal supply voltage V₁ becomes equal to or larger than the minimum operating voltage V₁ₘᵢₙ (t₁₂=t−t₀), the measurement end comparator 22 of the voltage comparison section 11-1 sets the signal level of the measurement end signal 20-1-2 high. Here, the AND circuit 38 holds the output signal level low independently from the change in the signal level of the measurement end signal 20-1-2.

At this time, the RS flip-flop35 holds the output signal level high, and the AND circuit 36 outputs the clock signal CLK. The counter 32 adds 1 when the signal level of the output signal from the AND circuit 36 changes from low to high.

Next, when the internal supply voltage V₂ becomes equal to or larger than the minimum operating voltage V₂ₘᵢₙ (t₁₂=t−t₀), the measurement end comparator 22 of the voltage comparison section 11-2 sets the signal level of the measurement end signal 20-2-2 high.

When the signal levels of both the measurement end signals 20-1-2 and 20-2-2 become high, the AND circuit 38 of the monitoring controller 13 sets the output signal level high. In response to the transition edge of the output signal of the AND circuit 38 to the high level, the RS flip-flop35 sets the output signal level low. Since the output signal level outputted from the RS flip-flop35 is low, the AND circuit 36 stops the outputting of the clock signal CLK, and the counter 32 ends the counting.

The time comparison section 34 compares a count value t₁₂ counted by the counter 32 and a set count value tₗᵢₘᵢₜ (100 [ms]).

The count value t₁₂ is within the set count value tₗᵢₘᵢₜ (t₁₂≦tₗᵢₘᵢₜ). In this case, the time comparison section 34 outputs the normal information OK as a monitoring result 30 to the output device 9 via the result output electrode pad 8. The normal information OK indicates that the internal supply voltages V₁ and V₂ are desired internal supply voltages and that the power-on time difference is also desired time difference tₗᵢₘᵢₜ.

When the count value t₁₂ exceeds the set count value tₗᵢₘᵢₜ (t₁₂>tₗᵢₘᵢₜ), the time comparison section 34 outputs the irregular information NG as a monitoring result 30 to the output device 9 via the result output electrode pad 8. The irregular information NG indicates that at least one of the internal supply voltages V₁ and V₂ is not a desired internal supply voltage or that the power-on time difference is also equal to or larger than the desired time difference tₗᵢₘᵢₜ.

According to the description given above, the semiconductor device 1 according to the second embodiment of the present invention is capable of, in addition to providing the effects of the first embodiment, executing a test mode for the prescription of the power-on time difference.

The semiconductor device 1 of embodiments of the present invention monitors the rising of the internal supply voltage, but the same configuration is applicable to a case where the fall of the internal supply voltage is monitored. In this case, to the input of the measurement start comparator 21, the minimum operating voltage Vⱼₘᵢₙ, instead of the set voltage Vⱼₛₜ, is supplied. To the input of the measurement end comparator 22, the set voltage Vⱼₛₜ, instead of the minimum operating voltage Vⱼₘᵢₙ, is supplied, thereby permitting the monitoring the fall of the internal supply voltages.

What is claimed is:

1. A semiconductor device comprising:
an electrode pad to which a supply voltage is supplied from an input power source;
an internal circuit to which the supply voltage is supplied as an internal supply voltage and configured to operate when the internal supply voltage is within a range of an operating voltage; and
a monitoring unit configured to monitor a rise time of the internal supply voltage changing from a set voltage set to be lower than the operating voltage to the operating voltage.

2. The semiconductor device according to claim 1, wherein the monitoring unit includes:
a measurement start comparator configured to output a measurement start signal when the internal supply voltage is equal to or higher than the set voltage;
a measurement end comparator configured to output a measurement end signal when the internal supply voltage is within the operating voltage; and
a monitoring controller configured to monitor an interval time between the output of the measurement start signal and the output of the measurement end signal as the rise time.

3. The semiconductor device according to claim 2, wherein the measurement end comparator ends the output of the measurement end signal when the internal supply voltage is lower than a minimum value of the operating voltage.

4. The semiconductor device according to claim 2, wherein the monitoring controller includes:
a counter configured to start counting of the rise time when the measurement start signal is outputted;
a counter controller configured to end the counting by the counter when the measurement end signal is outputted; and
a time comparator configured to output a result of a comparison between a count value counted by the counter and a preset count value as a monitoring result.

5. The semiconductor device according to claim 4, wherein the time comparator outputs irregular information indicating the rise time is not equal to or lower than a desired time when the count value is over the set count value.

6. The semiconductor device according to claim 4, wherein the number of the input power source, the internal supply voltage and the electrode pad is n (n is an integer larger than 1), and the n input power sources supply the n internal supply voltages via the n electrode pads to the internal circuit, and
the monitoring unit includes:
n voltage comparators to which the n internal supply voltages are supplied respectively and each of the n voltage comparators includes the measurement start comparator and the measurement end comparator; and
a selector configured to select j-th voltage comparator of the n voltage comparators in response to j-th selection signal (j is an integer satisfying 1≦j≦n), and
the monitoring controller monitors an interval between an output of the measurement start signal from the j-th voltage comparator and an output of the measurement end signal from the j-th voltage comparator as the rise time.

7. The semiconductor device according to claim 4, wherein the input power source, the electrode pad and the internal supply voltage are 2 respectively, and the 2 input power sources supply the 2 internal supply voltages via the 2 electrode pads to the internal circuit, and
the monitoring unit further comprises 2 voltage comparators, the 2 internal supply voltages are supplied to the 2 voltage comparators respectively, and each of the 2 voltage comparators includes the measurement start comparator and the measurement end comparator,
the counter starts counting of the rise time when the voltage comparator of either of the 2 voltage comparator outputs the measurement start signal, and
the counter controller stops a counting of the counter when the voltage comparator of both of the 2 voltage comparator outputs the measurement end signal.

8. The semiconductor device according to claim 4, wherein the monitoring unit includes a clock generator configured to output a clock signal, and
the rise time is counted by counting the clock signal.

9. The semiconductor device according to claim 1, wherein the monitoring unit monitors the rise time in response to an input of a test mode signal.

10. The semiconductor device according to claim 3, further comprising:
a result output electrode pad, and
the time comparator outputs the monitoring result to an output device via the result output electrode pad.

11. The semiconductor device according to claim 10, wherein the output device is an alarm outputs the monitoring result through a sound.

12. The semiconductor device according to claim 10, wherein the output device is a display visually outputs the monitoring result.

13. A semiconductor system comprising:
a semiconductor device; and
an input power source configured to supply a supply voltage to the semiconductor device,
wherein the semiconductor device includes:
an electrode pad to which the supply voltage is supplied;
an internal circuit to which the supply voltage is supplied as an internal supply voltage and configured to operate when the internal supply voltage is within a range of an operating voltage; and
a monitoring unit configured to monitor a rise time of the internal supply voltage changing from a set voltage set to be lower than the operating voltage to the operating voltage.
